(19) United States
(12) Patent Application Publication
(10) Pub. No.: US 2026/0032996 A1
(43) Pub. Date: Jan. 29, 2026

(54) SEMICONDUCTOR DEVICE WITH BACKSIDE POWER DELIVERY NETWORK

(71) Applicant: SAMSUNG ELECTRONICS CO., LTD., Suwon-si (KR)

(72) Inventors: Junghyun Kim, Suwon-si (KR); Kiil Kim, Suwon-si (KR); Hyonwook Ra, Suwon-si (KR); Keunhee Bai, Suwon-si (KR); Heeyeon Byun, Suwon-si (KR); Cheolin Jang, Suwon-si (KR)

(73) Assignee: SAMSUNG ELECTRONICS CO., LTD., Suwon-si (KR)

(21) Appl. No.: 19/258,098

(22) Filed: Jul. 2, 2025

(30) Foreign Application Priority Data
Jul. 29, 2024 (KR) 10-2024-0100080

(51) Int. Cl. H10D 84/83; H10D 30/00; H10D 30/01; H10D 30/43; H10D 62/10; H10D 62/13; H10D 64/23; H10D 84/01; H10D 86/00

(52) U.S. Cl. CPC H10D 84/832; H10D 30/43; H10D 30/503; H10D 62/121; H10D 62/151; H10D 64/256; H10D 84/8312; H10D 86/201; H10D 30/014; H10D 30/0191; H10D 84/0149

(57) ABSTRACT

A semiconductor device includes: active regions extending in a first direction on a substrate; a device isolation layer; gate structures intersecting the active regions and extending in a second direction; a plurality of channel layers on the active regions spaced apart from each other in a third direction and surrounded by the gate structures; first and second source/drain regions spaced apart from each other, the source/drain regions being connected to the plurality of channel layers and in recess regions on both sides of the gate structures; sidewall spacer layers on side surfaces of the source/drain regions; and a backside contact plug penetrating one of the active regions, and contacting a lower surface of the first source/drain region, wherein the active regions include a step region, and wherein the first active region extends onto side surfaces of at least an upper region of the backside contact plug in the second direction.

### CROSS-REFERENCE TO RELATED APPLICATION

This application is based on and claims priority to Korean Patent Application No. 10-2024-0100080, filed on Jul. 29, 2024 in the Korean Intellectual Property Office, the entire disclosure of which is incorporated herein by reference for all purposes.

### BACKGROUND

The present disclosure relates to a semiconductor device.

As the demand for high performance, high speed, and/or multi-functionality of semiconductor devices increases, the degree of integration of semiconductor devices is also increasing. In accordance with the trend toward high integration of semiconductor devices, semiconductor devices having a backside power delivery network (BSPDN) structure in which power rails are disposed on a rear surface of a wafer are being developed. In addition, efforts are being made to develop semiconductor devices including fin field-effect transistors (FinFETs) with three-dimensional channels to overcome the limitations in operating characteristics due to size reduction of planar metal oxide semiconductor FETs (MOSFETs).

### SUMMARY

Provided is a semiconductor device having improved reliability.

According to an aspect of the disclosure, a semiconductor device includes: active regions extending in a first direction on a substrate; a device isolation layer defining the active regions on the substrate; gate structures intersecting the active regions on the substrate and extending in a second direction; a plurality of channel layers on the active regions, wherein the plurality of channel layers are spaced apart from each other in a third direction perpendicular to an upper surface of the substrate, and are surrounded by the gate structures; source/drain regions comprising a first source/drain region and a second source/drain region spaced apart from each other, wherein the source/drain regions are in recess regions in which the active regions are recessed on both sides of the gate structures, and wherein the source/drain regions are connected to the plurality of channel layers; sidewall spacer layers on a portion of each side surface of each of the source/drain regions in the second direction; and a backside contact plug penetrating a first active region among the active regions, and contacting a lower surface of the first source/drain region, wherein each of the active regions comprises a step region in which a width of each of the active regions in the second direction increases below the plurality of channel layers, and wherein the first active region extends onto side surfaces of at least an upper region of the backside contact plug in the second direction.

According to an aspect of the disclosure, a semiconductor device includes: an active region extending in a first direction on a substrate; a gate structure intersecting the active region on the substrate and extending in a second direction; a plurality of channel layers on the active region, wherein the plurality of channel layers are spaced apart from each other in a third direction perpendicular to an upper surface of the substrate and are surrounded by the gate structure; a first source/drain region and a second source/drain region, wherein the first and the second source/drain regions are in recess regions in which the active region is recessed on both sides of the gate structure, and wherein the first and the second source/drain regions are connected to the plurality of channel layers; and a backside contact plug contacting a lower surface of the first source/drain region, wherein the active region extends onto a side surface of the backside contact plug in the second direction.

According to an aspect of the disclosure, a semiconductor device includes: a substrate structure; source/drain regions comprising a first source/drain region and a second source/drain region spaced apart from each other; gate structures extending in one direction on the substrate structure, wherein the source/drain regions are arranged on either side of the gate structures; sidewall spacer layers on a portion of each of side surface of the source/drain regions on an outside of the gate structures; a backside contact plug connected to the first source/drain region through a lower surface of the first source/drain region; and a place holder layer below the second source/drain region, wherein an upper end of the substrate structure protrudes into the sidewall spacer layers on the outside of the gate structures.

### BRIEF DESCRIPTION OF DRAWINGS

The above and other aspects and features of certain embodiments of the present disclosure will be more clearly understood from the following detailed description, taken in conjunction with the accompanying drawings, in which:

FIG. 1 is a plan view illustrating a semiconductor device according to one or more embodiments;

FIGS. 2A, 2B and 2C are cross-sectional views illustrating a semiconductor device according to one or more embodiments;

FIG. 3 is an enlarged partial view illustrating a semiconductor device according to one or more embodiments;

FIG. 4 is a cross-sectional view illustrating a semiconductor device according to one or more embodiments;

FIG. 5 is a cross-sectional view illustrating a semiconductor device according to one or more embodiments;

FIGS. 6A and 6B are cross-sectional views illustrating a semiconductor device according to one or more embodiments;

FIG. 7 is a cross-sectional view illustrating a semiconductor device according to one or more embodiments;

FIG. 8 is a plan view illustrating a semiconductor device according to one or more embodiments;

FIGS. 9A, 9B, and 9C are cross-sectional views illustrating semiconductor devices according to one or more embodiments; and

FIGS. 10A, 10B, 11, 12, 13, 14, 15, 16, 17A, 17B, 18A, 18B, 19A, 19B, 20A, 20B, 21A, 21B, 22A, and 22B are drawings illustrating a method of manufacturing a semiconductor device according to one or more embodiments.

### DETAILED DESCRIPTION

Hereinafter, certain embodiments of the present disclosure will be described with reference to the accompanying drawings. Hereinafter, it can be understood that terms such as “on,” “upper,” “upper portion,” “upper surface,” “below,” “lower,” “lower portion,” “lower surface,” “side surface,” and the like may be denoted by reference numerals and refer to the drawings, except where otherwise indicated.

In the following description, like reference numerals refer to like elements throughout the specification.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

The various actions, acts, blocks, steps, or the like in the flow diagrams may be performed in the order presented, in a different order, or simultaneously. Further, in one or more embodiments, some of the actions, acts, blocks, steps, or the like may be omitted, added, modified, skipped, or the like without departing from the scope of the disclosure.

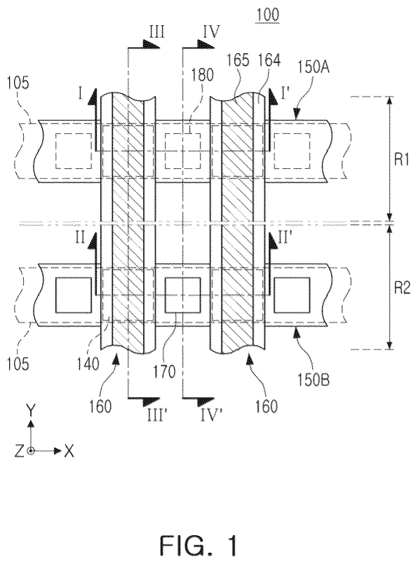

FIG. 1 is a plan view illustrating a semiconductor device according to one or more embodiments. For convenience of explanation, only some components of the semiconductor device are illustrated in FIG. 1.

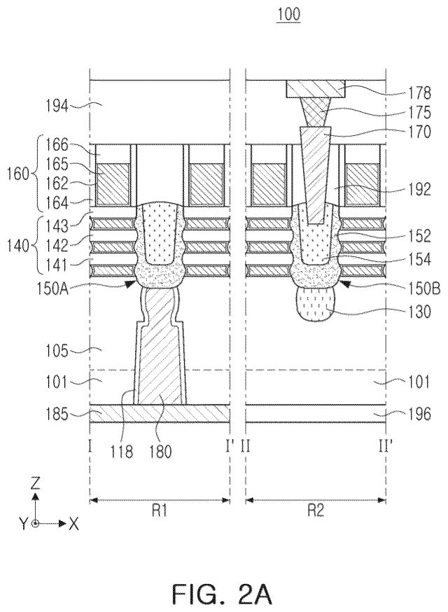

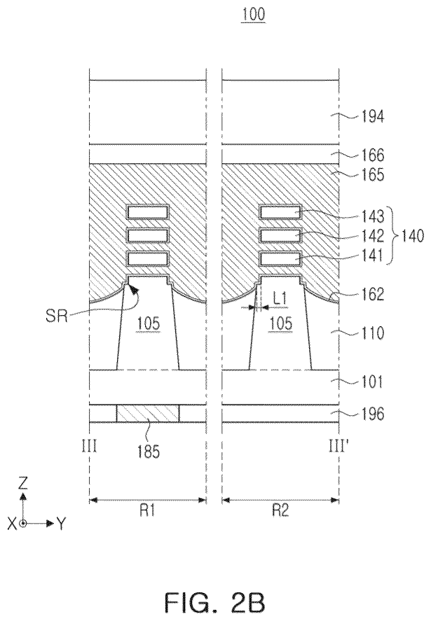

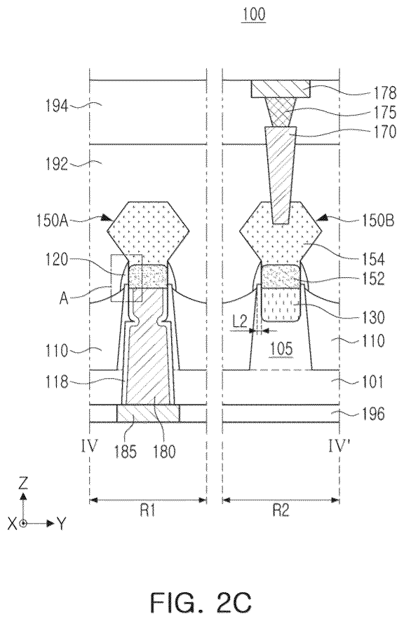

FIGS. 2A to 2C are cross-sectional views illustrating semiconductor devices according to one or more embodiments. FIG. 2A illustrates a cross-section of the semiconductor device of FIG. 1 taken along the cutting lines I-I′ and II-II′, FIG. 2B illustrates a cross-section of the semiconductor device of FIG. 1 taken along the cutting line III-III′, and FIG. 2C illustrates a cross-section of the semiconductor device of FIG. 1 taken along the cutting line IV-IV′.

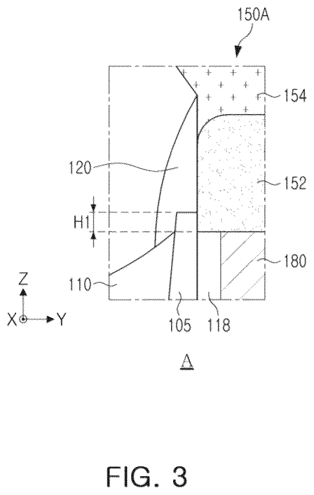

FIG. 3 is an enlarged partial view illustrating a semiconductor device according to one or more embodiments. FIG. 3 illustrates an enlarged view of region “A” of FIG. 2C.

Referring to FIGS. 1 to 3, a semiconductor device 100 may include a substrate 101 having first and second regions R1 and R2, active regions 105 on the substrate 101, channel structures 140 disposed vertically on the active regions 105 to be spaced apart from each other and including first to third channel layers 141, 142, and 143, gate structures 160 intersecting the active regions 105 and extending and respectively including a gate electrode 165, first and second source/drain regions 150A and 150B contacting the channel structures 140 and respectively disposed in the first and second regions R1 and R2, backside contact plugs 180 connected to the first source/drain regions 150A, and front contact plugs 170 connected to the second source/drain regions 150B. The semiconductor device 100 may further include a device isolation layer 110, a contact insulating layer 118, sidewall spacer layers 120, a place holder layer 130 below the second source/drain region 150B, an upper contact 175 and an upper interconnection line 178 on the front contact plug 170, a backside power structure 185 connected to the backside contact plug 180, and first to third interlayer insulating layers 192, 194, and 196.

In the semiconductor device 100, the active regions 105 may have a fin structure, and the gate electrodes 165 may be disposed between the active regions 105 and the channel structure 140, between the first to third channel layers 141, 142, and 143 of the channel structure 140, and on the channel structure 140. Accordingly, the semiconductor device 100 may include transistors having a Multi Bridge Channel FET (MBCFET™) structure or nanosheet transistor structure, which is a gate-all-around type field effect transistor.

The substrate 101 may have an upper surface extending in the X-direction and the Y-direction. The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, or a semiconductor on insulator (SeOI) layer.

The substrate 101 may include first and second regions R1 and R2, and the first and second regions R1 and R2 may be regions, which are adjacent to or spaced apart from each other. In the first region R1, first source/drain regions 150A and backside contact plugs 180 may be disposed, and in the second region R2, second source/drain regions 150B and front contact plugs 170 may be disposed. For example, the first and second regions R1 and R2 may be regions in which transistors comprising different circuits are disposed, and may be regions in which transistors of the same or different conductivity types are disposed. In one or more embodiments, the first and second regions R1 and R2 may be regions in which a channel length of the transistor, for example, lengths of the first to third channel layers 141, 142, and 143 in the X-direction are different. The first and second regions R1 and R2 may be referred to as regions of the semiconductor device 100, rather than regions of the substrate 101.

The active regions 105 may be defined by the device isolation layer 110 on the substrate 101, and may be disposed to extend in a first direction, for example, in a X-direction. Depending on the description, it may also be possible to describe the active regions 105 as a portion of the substrate 101. In some claims, the active regions 105 may be referred to as a substrate structure together with the substrate 101. The active regions 105 may partially protrude onto the device isolation layer 110, so that upper surfaces of the active regions 105 may be disposed on a level higher than an upper surface of the device isolation layer 110. The active regions 105 may be formed as a portion of the substrate 101, or may include an epitaxial layer grown from the substrate 101. However, on both sides of the gate structures 160, the active regions 105 are partially recessed to form recess regions, and first and second source/drain regions 150A and 150B may be disposed in the recess regions.

The active regions 105 may have a step region SR of which a width thereof in a Y-direction changes discontinuously. The step region SR may be a region having a surface in which the active region 105 extends horizontally as the width discontinuously increases from an upper portion to a lower portion of the active region 105. As illustrated in FIG. 2B, the active region 105 may include an upper region on the step region SR and a lower region below the step region SR. The upper region may have a first width equal to or greater than a width of a first channel layer 141 which is the lowermost channel layer, and the lower region may have a second width greater than the first width. The active region 105 may have an upper surface of which a width thereof increases discontinuously between the upper region and the lower region and extending horizontally. In the step region SR, a first length L1 of the horizontal upper surface or a difference between the second width and the first width may be in a range of about 2 nm to about 5 nm.

As illustrated in FIG. 2C, the active region 105 may have a form in which a portion including the upper region is removed on the outside of the gate structure 160. A level of an upper end of the active region 105 on the outside of the gate structure 160 may be equal to or lower than a level of the step region SR below the gate structure 160. In the active region 105, both ends thereof in the Y-direction may extend and protrude upwardly onto side surfaces of at least an upper region of the backside contact plug 180, or may extend and protrude onto side surfaces of the place holder layer 130. On the outside of the gate structure 160, the active regions 105 may be disposed on the entire side surfaces of the backside contact plug 180, at least partially cover the side surfaces and the lower surface of the place holder layer 130, and at least partially cover a portion of side surfaces of the first epitaxial layers 152 of the first and second source/drain regions 150A and 150B. The upper ends of the active regions 105 may be located on a level higher than the upper surface of the place holder layer 130 and the upper surface of the backside contact plug 180. A second length L2 of the active regions 105 on side surfaces of the first and second source/drain regions 150A and 150B, which may also be referred to as a thickness of the active region 105 on the side surfaces of the first and second source/drain regions 150A and 150B, may be equal to or greater than the first length L1.

The active regions 105 may respectively include a well region including impurities. For example, the well region may include p-type impurities such as boron (B), gallium (Ga), or aluminum (Al), or n-type impurities such as phosphorus (P), arsenic (As), or antimony (Sb). The well region may be located, for example, at a predetermined depth from an upper surface of each of the active regions 105.

The device isolation layer 110 may define active regions 105 on the substrate 101. The device isolation layer 110 may be formed, for example, by a shallow trench isolation (STI) process. The device isolation layer 110 may expose at least upper surfaces of the active regions 105, and may also expose a portion of an upper portion thereof. The device isolation layer 110 may have a curved upper surface so as to have a higher level to be more adjacent to the active regions 105. The device isolation layer 110 may be formed of an insulating material. The device isolation layer 110 may be, for example, an oxide, a nitride, or a combination thereof.

The gate structures 160 may be disposed to extend in one direction, for example, in the Y-direction, on the active regions 105. A channel region of transistors may be formed in a channel structure 140 intersecting a gate electrode 165 of a gate structures 160. The gate structures 160 may be disposed to be spaced apart from each other in the X-direction. Each of the gate structures 160 may include gate dielectric layers 162, gate spacer layers 164, a gate electrode 165, and a gate capping layer 166.

The gate dielectric layers 162 may be disposed between the active region 105 and the gate electrode 165 and between the channel structure 140 and the gate electrode 165, and may be disposed to cover at least a portion of the surfaces of the gate electrode 165. For example, the gate dielectric layers 162 may be disposed to surround all surfaces, except for an uppermost surface of the gate electrode 165. The gate dielectric layers 162 may extend between the gate electrode 165 and the gate spacer layers 164, but the present disclosure is not limited thereto. The gate dielectric layer 162 may include an oxide, a nitride, or a high-k material. The high-k material may mean a dielectric material having a higher dielectric constant than silicon oxide (SiO₂). The high-dielectric constant material may be, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). According to one or more embodiments, the gate dielectric layer 162 may be formed of a multilayer structure.

The gate electrode 165 may include a conductive material, for example, a metal nitride such as titanium nitride (TiN), tantalum nitride (TaN), or tungsten nitride (WN), and/or a metal material such as aluminum (Al), tungsten (W), or molybdenum (Mo), or a semiconductor material such as doped polysilicon. According to one or more embodiments, the gate electrode 165 may be formed of a multilayer structure. The gate electrodes 165 may be connected to gate contact plugs disposed thereabove.

Gate spacer layers 164 may be disposed on both side surfaces of the gate electrode 165 on the channel structure 140. The gate spacer layers 164 may insulate the source/drain regions 150 and the gate electrodes 165. According to embodiments, a shape of upper portions of the gate spacer layers 164 may be variously changed, and the gate spacer layers 164 may be formed of a multilayer structure. The gate spacer layers 164 may include at least one of an oxide, a nitride, or an oxynitride, and may be formed of, for example, a low-k film.

The gate capping layer 166 may be disposed on the gate electrode 165 and may be disposed between the gate spacer layers 164. In one or more embodiments, a lower surface of the gate capping layer 166 may also have a convex shape facing downward. The gate capping layer 166 may include an insulating material, and may include at least one of an oxide, a nitride, or an oxynitride, for example.

The channel structures 140 may include first to third channel layers 141, 142, and 143, which are two or more plurality of channel layers disposed to be spaced apart from each other in a direction perpendicular to an upper surface of each of the active regions 105, for example, in the Z direction, on each of the active regions 105. The first to third channel layers 141, 142, and 143 may be connected to the first and second source/drain regions 150A and 150B, and may be spaced apart from the upper surfaces of the active regions 105. The first to third channel layers 141, 142, and 143 may have a width in the Y-direction, which is the same or similar to the active regions 105 and a width in the X-direction, which is the same or similar to the gate structures 160. In one or more embodiments, the first to third channel layers 141, 142, and 143 may have widths in the Y-direction which decrease toward a channel layer disposed thereon. For example, the second channel layer 142 may have a smaller width than the first channel layer 141, and the third channel layer 143 may have a smaller width than the second channel layer 142. The number and shape of each of the channel layers 141, 142, and 143 of the channel structures may vary in one or more embodiments. In one or more embodiments, the semiconductor device 100 may have a FinFET structure having a channel structure different from the channel structure 140.

The first to third channel layers 141, 142, and 143 may be formed of a semiconductor material, and may include, for example, at least one of silicon (Si), silicon germanium (SiGe), or germanium (Ge). The first to third channel layers 141, 142, and 143 may be formed of, for example, the same material as the substrate 101. According to one or more embodiments, the first to third channel layers 141, 142, and 143 may also include an impurity region located in a region adjacent to the source/drain regions 150.

The first and second source/drain regions 150A and 150B may be disposed on both sides of the gate structures 160, to contact the channel structures 140, respectively. The first and second source/drain regions 150A and 150B may be disposed to at least partially cover side surfaces of each of the first to third channel layers 141, 142, and 143 of the channel structure 140 in the X-direction. The first source/drain regions 150A may be disposed on the first region R1 of the substrate 101, and may be respectively connected to backside contact plugs 180 through lower surfaces or lower ends thereof, and the second source/drain regions 150B may be disposed on the second region R2 of the substrate 101, and may be respectively connected to front contact plugs 170 through upper surfaces or upper ends thereof. The second source/drain region 150B may have a shape recessed by the front contact plug 170. In one or more embodiments, the second source/drain region 150B may be disposed as a dummy source/drain region, which is not connected to the front contact plug 170. The upper surfaces of the first and second source/drain regions 150A and 150B may be located on the same level as or higher than the lower surface of the gate electrode 165 on the channel structure 140, and the level may be variously changed in one or more embodiments.

As illustrated in FIG. 2C, in a cross-section on the outside of the gate structures 160 in the Y-direction, the first and second source/drain regions 150A and 150B may include upper regions having a polygonal shape and lower regions connected to the backside contact plug 180 or the place holder layer 130 below the upper region. The upper regions may be arranged on the sidewall spacer layers 120. However, in one or more embodiments, the shape of the upper regions are not limited to the shape illustrated in FIG. 2C, and may have a curved polygonal, oval, or circular shape. The sidewall spacer layers 120 may cover at least a portion of side surfaces of the lower regions. The lower regions may have side surfaces extending substantially vertically.

Each of the first and second source/drain regions 150A and 150B may include first and second epitaxial layers 152 and 154. The first epitaxial layer 152 may at least partially cover side surfaces of each of the first to third channel layers 141, 142, and 143 in the X-direction, and may at least partially cover side surfaces of the gate structures 160 below the channel structure 140 in the X-direction. The first epitaxial layer 152 may extend to at least partially cover an inner sidewall and a bottom surface of a recess region in which each of the first and second source/drain regions 150A and 150B are disposed. The first epitaxial layer 152 may have an outer surface protruding convexly toward the gate structure 160 below the first to third channel layers 141, 142, and 143, and thus may have a curve on the outer surface. However, the shape of the outer surface of the first epitaxial layer 152 is not limited to the shape illustrated in FIG. 2A. In the first source/drain region 150A, the first epitaxial layer 152 may be in contact with the backside contact plug 180. In the second source/drain region 150B, the first epitaxial layer 152 may be spaced apart from the front contact plug 170 by the second epitaxial layer 154.

The second epitaxial layer 154 may at least partially cover the first epitaxial layer 152, and fill the recess region. In the first source/drain region 150A, the second epitaxial layer 154 may be spaced apart from the backside contact plug 180 by the first epitaxial layer 152. In the second source/drain region 150B, the second epitaxial layer 154 may be in contact with the front contact plug 170. A length of the second epitaxial layer 154 in the X-direction may be greater than a thickness of the first epitaxial layer 152 on one side surface of the channel structure 140. In one or more embodiments, each of the first and second source/drain regions 150A and 150B may further include a third epitaxial layer on an upper surface of the second epitaxial layer 154.

The first and second source/drain regions 150A and 150B may include at least one of a semiconductor material, for example, silicon (Si) and germanium (Ge), and may further include impurities. The first and second epitaxial layers 152 and 154 may have different compositions. A concentration of a non-silicon element of the second epitaxial layer 154 may be higher than a concentration of a non-silicon element of the first epitaxial layer 152. The non-silicon element may be, for example, germanium (Ge) and/or a doping element. The doping element may include the n-type impurities or the p-type impurities. For example, the second epitaxial layer 154 may have a higher concentration of impurities than the first epitaxial layer 152. Accordingly, resistivity of the second epitaxial layer 154 may be less than resistivity of the first epitaxial layer 152.

In one or more embodiments, the semiconductor device 100 may further include internal spacer layers disposed between side surfaces of the first and second source/drain regions 150A and 150B in the X-direction and the gate dielectric layers 162. The internal spacer layers may include an insulating material.

The sidewall spacer layers 120 may be disposed on the upper ends of the active regions 105 and the device isolation layer 110 on the outside of the gate structures 160. The sidewall spacer layers 120 may at least partially cover both side surfaces of the lower regions of the first and second source/drain regions 150A and 150B in the Y-direction.

As illustrated in FIG. 2C and FIG. 3, the sidewall spacer layer 120 may at least partially cover the upper end of the active region 105 and extend onto the device isolation layer 110. An upper end of the device isolation layer 110 and an upper end of the active region 105, which are in contact with the sidewall spacer layer 120, may be located on different levels. The sidewall spacer layer 120 may at least partially cover a portion of an upper surface of the protruding region of the active region 105 and a side surface extending from the upper surface. Accordingly, the upper end of the active region 105 may have a shape protruding into the sidewall spacer layer 120, and a first height H1, which is a protruding length of the upper end, may be variously changed in one or more embodiments. The sidewall spacer layer 120 may have a lower surface, bent along the upper end of the active region 105. The lower surface of the sidewall spacer layer 120 may have different degrees of inclination in a portion in contact with an upper surface of the active region 105 and in a portion in contact with an upper surface of the device isolation layer 110. However, in one or more embodiments, the upper end of the active region 105 and an upper end of the device isolation layer 110 in contact with the upper end of the active region 105 may be located on substantially the same level, and in this case, the first height H1 may be zero. However, even in this case, the lower surface of the sidewall spacer layer 120 may have a profile that is angled and has different degrees of inclination on an upper surface of the active region 105 and an upper surface of the device isolation layer 110.

The sidewall spacer layer 120 may at least partially cover a side surface of the first epitaxial layer 152 protruding onto the active region 105, and may at least partially cover a portion of a side surface of a lower region of the second epitaxial layer 154. The sidewall spacer layers 120 may include an insulating material and may include at least one of an oxide, a nitride, or an oxynitride.

The place holder layer 130 may contact a lower surface of the second source/drain region 150B below the second source/drain region 150B. The place holder layer 130 may extend from a lower surface of the second source/drain region 150B into the active region 105. The entire surface of the place holder layer 130 may be covered with the second source/drain region 150B and the active region 105. The entire side surfaces of the place holder layer 130 in the Y-direction may be covered with the active region 105.

The place holder layer 130 may include at least one of a semiconductor material, for example, silicon (Si) or germanium (Ge), and may have a different composition than the first and second source/drain regions 150A and 150B. In one or more embodiments, the place holder layer 130 may further include impurities.

Backside contact plugs 180 may be disposed below the first source/drain regions 150A. The backside contact plugs 180 may penetrate the substrate 101 and the active region 105 and be connected to the first source/drain regions 150A and may apply an electrical signal to the first source/drain regions 150A.

Each of the backside contact plugs 180 may include a lower region penetrating the substrate 101 and the active region 105 and having a width decreasing upwardly, and an upper region disposed on the lower region of the backside contact plug 180 and having a shape corresponding to the place holder layer 130. The upper region of the backside contact plug 180 may have a smaller width than the lower region of the backside contact plug 180, but the present disclosure is not limited thereto. A point at which the width discontinuously changes may be formed between the upper region and the lower region. Accordingly, on the outside of the gate structures 160, at a level corresponding to a lower surface of the place holder layer 130, the active region 105 on side surfaces of the backside contact plug 180 may also have a point at which the thickness discontinuously changes. However, in one or more embodiments, the shape of the backside contact plug 180 may be variously changed.

The backside contact plug 180 may be disposed to contact a lower surface of the first epitaxial layer 152 of the first source/drain region 150A. In the present embodiment, the backside contact plug 180 may be spaced apart from the second epitaxial layer 154 by the first epitaxial layer 152. An upper end of the backside contact plug 180 may be located on a level lower than a lower surface of the lowermost first channel layer 141 and a lowermost surface of the gate structure 160. In one or more embodiments, the backside contact plug 180 may be partially recessed from the lower surface of the first source/drain region 150A.

The front contact plugs 170 may penetrate the first and second interlayer insulating layers 192 and 194 and be connected to second source/drain regions 150B, and may apply an electrical signal to the second source/drain regions 150B. The front contact plugs 170 may have inclined side surfaces with a width in a lower portion thereof being narrower than a width in an upper portion thereof, depending on an aspect ratio, but the present disclosure is not limited thereto. The front contact plugs 170 may be disposed in a recess of the second source/drain regions 150B from the upper surfaces. The front contact plugs 170 may extend from the upper portion, for example, to further below the lower surface of the uppermost third channel layer 143 of the channel structure 140, but the present disclosure is not limited thereto. For example, lower ends of the front contact plugs 170 may be located on a level between an upper surface of the second channel layer 142 and a lower surface of the third channel layer 143.

The backside contact plug 180 and the front contact plug 170 may include a metal material such as, for example, aluminum (Al), tungsten (W), or molybdenum (Mo). According to one or more embodiments, the backside contact plug 180 may include a metal-semiconductor compound layer, for example, a metal silicide layer, located at an interface with the first source/drain region 150A, and may further include a barrier layer forming side surfaces of the backside contact plug 180 and extending onto an upper surface of the metal-semiconductor compound layer. Similarly, the front contact plug 170 may include a metal-semiconductor compound layer, such as a metal silicide layer, located at an interface with the second source/drain region 150B, and may further include a barrier layer forming side surfaces of the front contact plug 170 and extending onto the upper surface of the metal-semiconductor compound layer. The barrier layer may include a metal nitride, such as, for example, titanium nitride (TiN), tantalum nitride (TaN), or tungsten nitride (WN). In one or more embodiments, numbers and arrangement of conductive layers forming each of the backside contact plug 180 and the front contact plug 170 may be variously changed.

In one or more embodiments, the front contact plug 170 and the backside contact plug 180 are disposed in the first and second regions R1 and R2, respectively, but the disposition of the front contact plug 170 and the backside contact plug 180 is not limited thereto. In one or more embodiments, the front contact plug 170 and the backside contact plug 180 may be respectively connected to the source/drain regions on both sides of one transistor.

The contact insulating layer 118 may be disposed to at least partially cover a side surface of the backside contact plug 180. The contact insulating layer 118 may be disposed between the backside contact plug 180 and the active region 105 and between the backside contact plug 180 and the substrate 101. The contact insulating layer 118 may electrically isolate the backside contact plug 180 from the active region 105 and the substrate 101. The contact insulating layer 118 may include an insulating material, for example, at least one of an oxide, a nitride, or an oxynitride. In one or more embodiments, the contact insulating layer 118 may partially remain on an edge region of the backside contact plug 180 and on a lower surface of the first source/drain region 150A.

The first interlayer insulating layer 192 may at least partially cover the first and second source/drain regions 150A and 150B. The second interlayer insulating layer 194 may at least partially cover the gate structures 160 and the first interlayer insulating layer 192. The third interlayer insulating layer 196 may at least partially cover a lower surface of the substrate 101. The first to third interlayer insulating layers 192, 194, and 196 may include at least one of an oxide, a nitride, or an oxynitride, and may include, for example, a low-k material. According to one or more embodiments, at least one of the first to third interlayer insulating layers 192, 194, or 196 may include a plurality of insulating layers.

The upper contact 175 may be disposed on the front contact plug 170 to connect the front contact plug 170 and an upper interconnection line 178. The backside power structure 185 may be connected to the backside contact plug 180 below the substrate 101. The backside power structure 185 may form a BSPDN applying a power or ground voltage together with the first backside contact plug 180, and may also be referred to as a backside power rail or a buried power rail. For example, the backside power structure 185 may be a buried interconnection line extending in one direction, for example, in the X-direction, but the shape and extension direction of the backside power structure 185 are not limited thereto. Each of the upper contact 175, the upper interconnection line 178, and the backside power structure 185 may include at least one of a conductive material, for example, tungsten (W), copper (Cu), aluminum (Al), cobalt (Co), ruthenium (Ru), titanium (Ti), or molybdenum (Mo).

The semiconductor device 100 may be packaged with the structure of FIGS. 2A to 2C to be flipped upside down so that the backside power structure 185 is disposed thereabove, but the packaging form of the semiconductor device 100 is not limited thereto.

In the description of the embodiments below, any description overlapping the description given above with reference to FIGS. 1 to 3 is omitted.

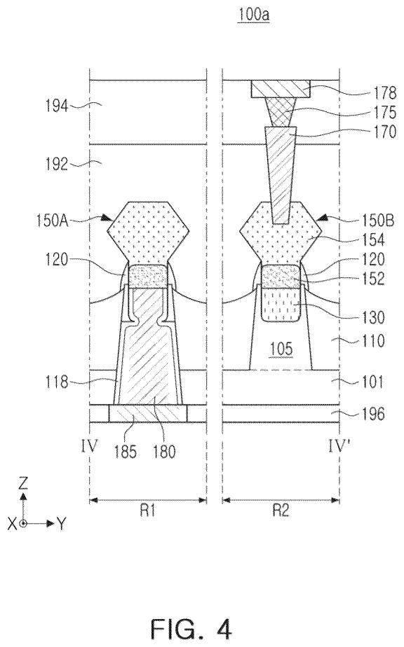

FIG. 4 is a cross-sectional view illustrating a semiconductor device according to one or more embodiments. FIG. 4 illustrates a region corresponding to FIG. 2C.

Referring to FIG. 4, in the semiconductor device 100a, the backside contact plug 180 may have a lower region not covered by the active region 105. The lower region may be a region located on a level below the lower surface of the place holder layer 130. In the present embodiment, the backside contact plug 180 may have a more expanded shape in the lower region, as compared to the embodiment of FIG. 2C. Accordingly, on the outside of the gate structures 160, the active region 105 may remain only on a side surface of an upper region of the backside contact plug 180. In one or more embodiments, on the outside of the gate structures 160, the active region 105 may have a shape which is partially recessed from the lower surface of the place holder layer 130.

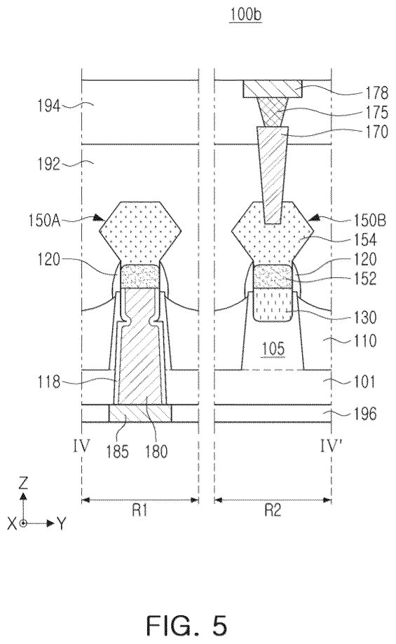

FIG. 5 is a cross-sectional view illustrating a semiconductor device according to one or more embodiments. FIG. 5 illustrates the region corresponding to FIG. 2C.

Referring to FIG. 5, in a semiconductor device 100b, on the outside of the gate structures 160, an upper end of the active region 105 may be located on a level lower than a level of an upper surface of the place holder layer 130. The upper end of the active region 105 may be located on a level lower than a level of an upper end of the backside contact plug 180. Accordingly, on the outside of the gate structures 160, the active region 105 may not cover the entire side surfaces of the place holder layer 130. The side surfaces of the place holder layer 130 exposed onto the active region 105 may be at least partially covered with the sidewall spacer layers 120. However, even in this case, the active region 105 may cover more than half, for example, more than 75%, of the side surfaces of the place holder layer 130.

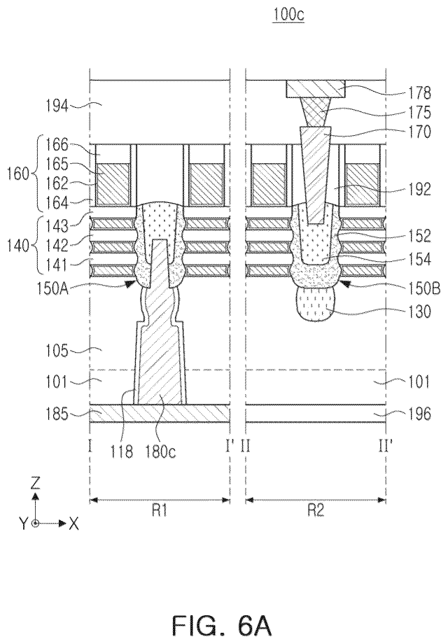

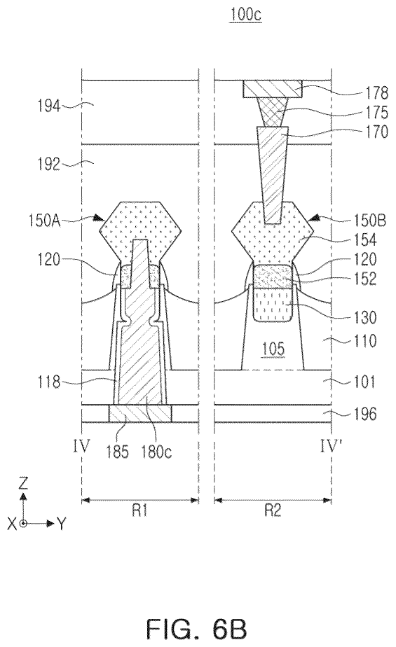

FIGS. 6A and 6B are cross-sectional views illustrating semiconductor devices according to one or more embodiments. FIGS. 6A and 6B illustrate regions corresponding to FIGS. 2A and 2C, respectively.

Referring to FIGS. 6A and 6B, in a semiconductor device 100c, the backside contact plug 180c may be formed in a recess of a lower surface of the first source/drain region 150A and may extend into the first source/drain region 150A. The backside contact plug 180c may include a lower region penetrating the substrate 101 and the active region 105 and of which a width thereof decreases upwardly, an upper region disposed on the lower region and having a shape corresponding to the place holder layer 130, and a recess region on the upper region where the recess region is formed in the recess in the first source/drain region 150A. A width of the recess region may be smaller than a width of the lower region and a width of the upper region, but the present disclosure is not limited thereto. The recess region may penetrate a first epitaxial layer 152 and have an upper end located within a second epitaxial layer 154. A depth at which the recess region extends into the first source/drain region 150A may vary in one or more embodiments.

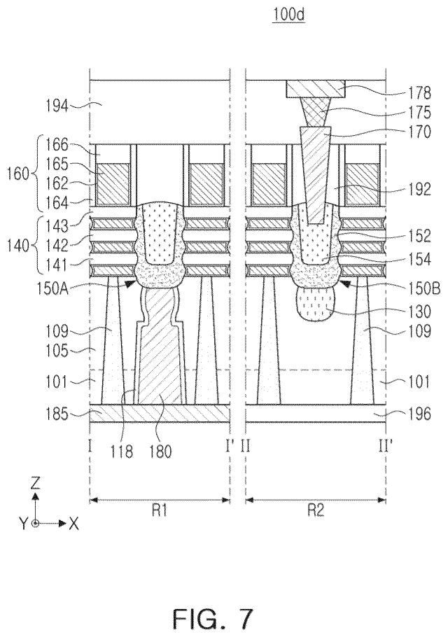

FIG. 7 is a cross-sectional view illustrating a semiconductor device according to one or more embodiments. FIG. 7 illustrates the region corresponding to FIG. 2A.

Referring to FIG. 7, a semiconductor device 100d may further include isolation structures 109 disposed on the lowermost surfaces of the gate structures 160.

The isolation structures 109 may penetrate the substrate 101 and the active regions 105 and may be connected to the gate structures 160. The isolation structures 109 may electrically isolate the backside contact plug 180 to be limited to a localized region. The isolation structures 109 may have a shape of which a width thereof increases toward a third interlayer insulating layer 196, but the shape of the isolation structures 109 is not limited thereto. The isolation structures 109 may include an insulating material, for example, an oxide, a nitride, or a combination thereof.

In one or more embodiments, the isolation structures 109 may be disposed only in the first region R1. In one or more embodiments, a substrate structure including the substrate 101 and the active regions 105 may be removed from a rear surface by a predetermined thickness, and the backside contact plug 180 may have an extended shape to fill the space between the isolation structures 109 below the rear surface of the substrate structure from which a portion has been removed.

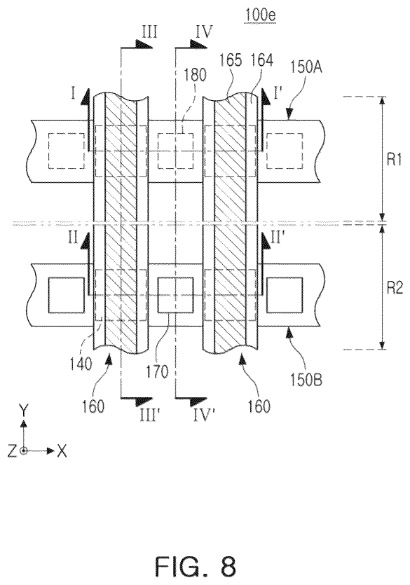

FIG. 8 is a plan view illustrating a semiconductor device according to one or more embodiments.

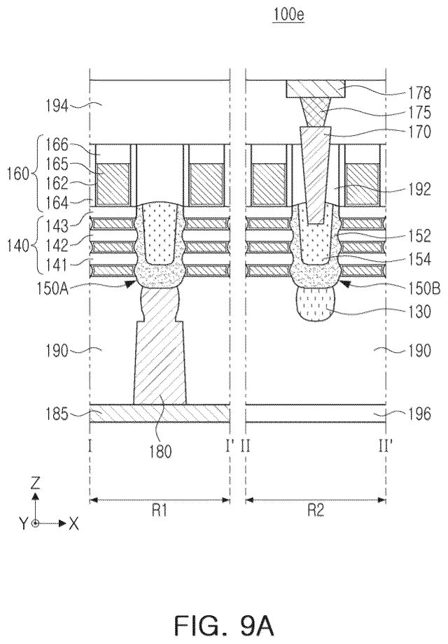

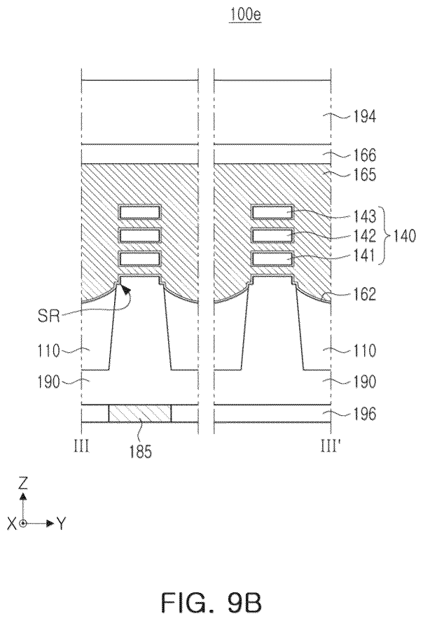

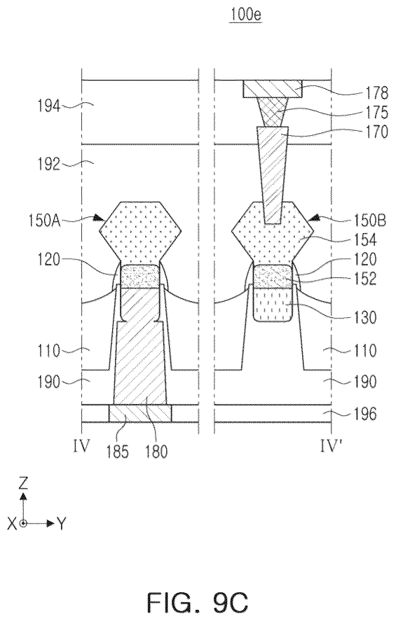

FIGS. 9A to 9C are cross-sectional views illustrating semiconductor devices according to one or more embodiments. FIG. 8 illustrates a region corresponding to FIG. 1, and FIGS. 9A to 9C illustrate regions corresponding to FIGS. 2A to 2C, respectively.

Referring to FIGS. 8 to 9C, unlike the embodiments of FIGS. 1 to 2C, a semiconductor device 100e may not include a substrate 101, an active region 105, and a contact insulating layer 118, but may include a substrate insulating layer 190.

The substrate insulating layer 190 may be a layer formed by removing and/or oxidizing the substrate 101 and the active region 105 formed of a semiconductor material during the manufacturing process. The substrate insulating layer 190 may be formed of an insulating material, and may include, for example, an oxide, a nitride, or a combination thereof. For example, the substrate insulating layer 190 may include a different material than the device isolation layer 110 and the sidewall spacer layers 120, such as silicon nitride. In one or more embodiments, the substrate insulating layer 190 may include the same material as the device isolation layer 110 and/or the sidewall spacer layers 120. In this case, interfaces between the substrate insulating layer 190, the device isolation layer 110, and the sidewall spacer layers 120 may or may not be distinct. According to one or more embodiments, the substrate insulating layer 190 may include a plurality of insulating layers. The substrate insulating layer 190 may also be referred to as a substrate structure.

The substrate insulating layer 190 may include first and second regions R1 and R2, surround a lower surface and a side surface of the place holder layer 130, and surround a side surface of the backside contact plug 180. The substrate insulating layer 190 may at least partially cover the side surface of the backside contact plug 180 on the outside of the gate structures 160, and an upper end thereof may protrude into the sidewall spacer layer 120. In addition, the description of the shape of the active region 105 described above with reference to FIGS. 1 to 2C may also be applied to the substrate insulating layer 190.

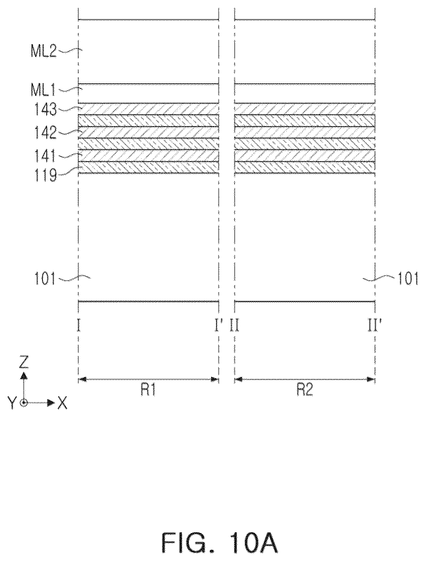

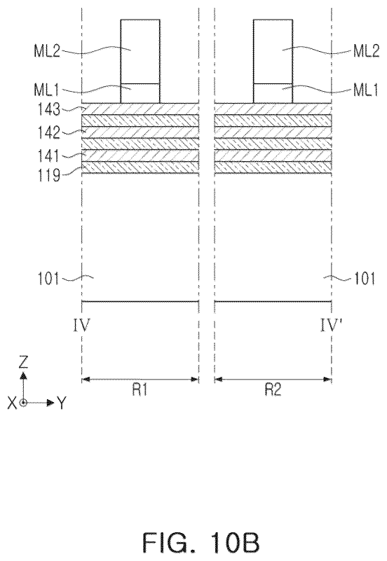

FIGS. 10A to 22B illustrate a process sequence for a method for manufacturing a semiconductor device according to one or more embodiments. FIGS. 10A to 22B illustrate an example embodiment of a method for manufacturing a semiconductor device of FIGS. 1 to 2C. FIGS. 10A, 16, 17A, 18A, 19A, 20A, 21A, and 22A illustrate cross-sections corresponding to FIG. 2A, and FIGS. 10B, 11, 12, 13, 14, 15, 17B, 18B, 19B, 20B, 21B, and 22B illustrate cross-sections corresponding to FIG. 2C.

Referring to FIGS. 10A and 10B, sacrificial layers 119 and first to third channel layers 141, 142, and 143 may be alternately stacked on the substrate 101, and first and second mask layers ML1 and ML2 may be formed.

The substrate 101 may include silicon (Si), germanium (Ge), or silicon germanium (SiGe). The substrate 101 may include a bulk wafer, an epitaxial layer, a silicon on insulator (SOI) layer, or a semiconductor on insulator (SeOI) layer.

The sacrificial layers 119 may be layers which are replaced with gate dielectric layers 162 and gate electrodes 165 through subsequent processes, as shown in FIGS. 2A and 2B. The sacrificial layers 119 may be formed of a material having etching selectivity with respect to the first to third channel layers 141, 142, and 143. The first to third channel layers 141, 142, and 143 may include a material different from the sacrificial layers 119. The sacrificial layers 119 and the first to third channel layers 141, 142, and 143 may include a semiconductor material including, for example, at least one of silicon (Si), silicon germanium (SiGe), or germanium (Ge), but may include different materials and may or may not include impurities. For example, the sacrificial layers 119 may include silicon germanium (SiGe), and the first to third channel layers 141, 142, and 143 may include silicon (Si).

The sacrificial layers 119 and the first to third channel layers 141, 142, and 143 may be formed by performing an epitaxial growth process from the substrate 101. The number of layers of channel layers 141, 142, and 143, alternately stacked with sacrificial layers 119, may vary in one or more embodiments.

The first and second mask layers ML1 and ML2 may be sequentially stacked on the third channel layer 143, and may be formed by being patterned in the shape of lines extending in the X-direction. The first and second mask layers ML1 and ML2 may be, for example, hard mask layers, and may include different materials. For example, the first mask layer ML1 may include silicon nitride, and the second mask layer ML2 may include silicon oxide.

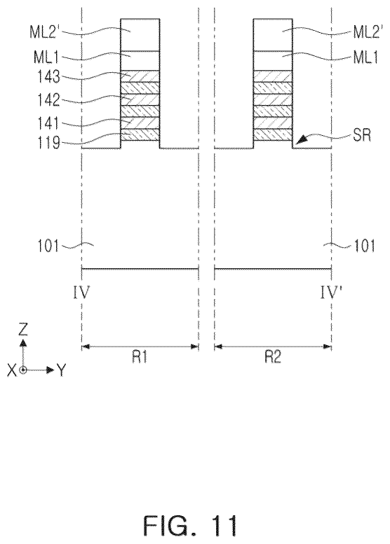

Referring to FIG. 11, the sacrificial layers 119 and the first to third channel layers 141, 142, and 143 may be partially removed.

In the sacrificial layers 119 and the first to third channel layers 141, 142, and 143, the regions exposed from the first and second mask layers ML1 and ML2 may be removed by an etching process. Thereby, patterned structures of the sacrificial layers 119 and the first to third channel layers 141, 142, and 143 may be formed. The substrate 101 may also be partially removed from the upper surface below the first channel layer 141 to form a step region SR. In the present operation, the second mask layer ML2 may be reduced in thickness to some extent, and is thus indicated as a second mask layer ML2′ in the following drawings.

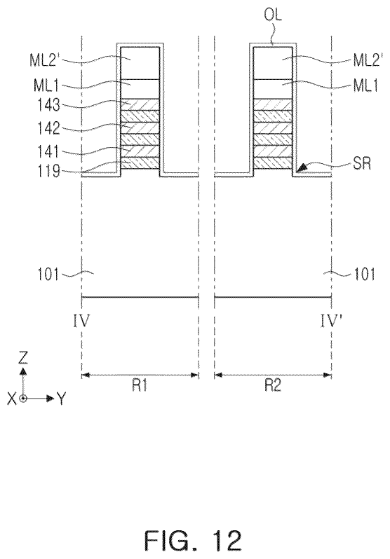

Referring to FIG. 12, a liner layer OL at least partially covering the patterned structures of the sacrificial layers 119 and the first to third channel layers 141, 142, and 143 may be formed.

The liner layer OL may at least partially cover upper and side surfaces of the entire structure including the patterned structure and first and second mask layers ML1 and ML2′, and at least partially covering the upper surface of the substrate 101, and may be formed conformally. A thickness of the liner layer OL may correspond to a first length L1 of FIG. 2B, and may be substantially equal to the first length L1. Therefore, by controlling the thickness of the liner layer OL, the first length L1 and a second length L2 of FIG. 2C may be controlled. The liner layer OL may include, for example, silicon oxide, but the present disclosure is not limited thereto.

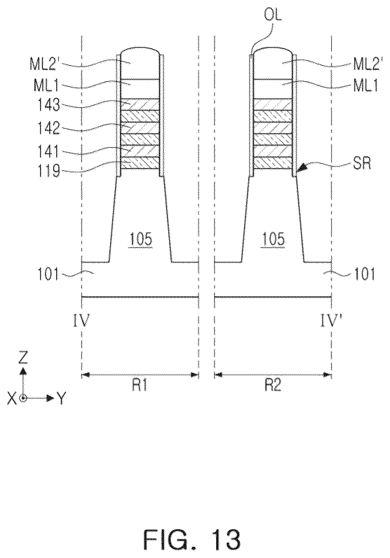

Referring to FIG. 13, a portion of the substrate 101 may be removed to form active regions 105.

The substrate 101 may be removed to a predetermined depth between the patterned structures of the sacrificial layers 119 and the first to third channel layers 141, 142, and 143 by an etching process, for example, a dry etching process. Thereby, active regions 105 extending in one direction, for example, in an X-direction, may be formed. The active regions 105 may be formed to have step regions SR along a lower end of the liner layer OL. During the etching process, the liner layer OL may be removed on the substrate 101 and a second mask layer ML2′, and the exposed second mask layer ML2′ may also be partially removed.

Thereby, active structures including an active region 105 and a stack structure of sacrificial layers 119 and first to third channel layers 141, 142, and 143, alternately stacked, may be formed. The active structures may be formed in the shape of lines extending in one direction, for example, the X-direction, and may be formed to be spaced apart from each other in the Y-direction.

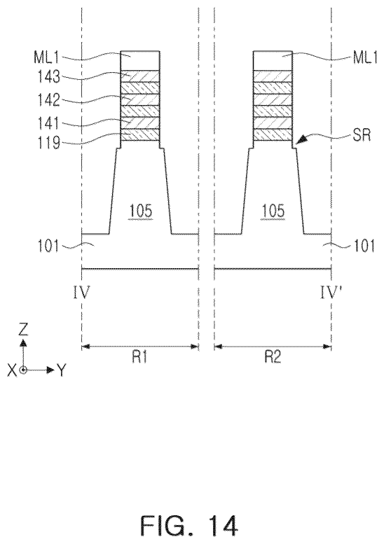

Referring to FIG. 14, a remaining liner layer OL and a second mask layer ML2′ may be removed.

The remaining liner layer OL and the second mask layer ML2′ may be removed, for example, by a wet cleaning process, such as a strip process. Accordingly, step regions SR of the active regions 105 may be exposed.

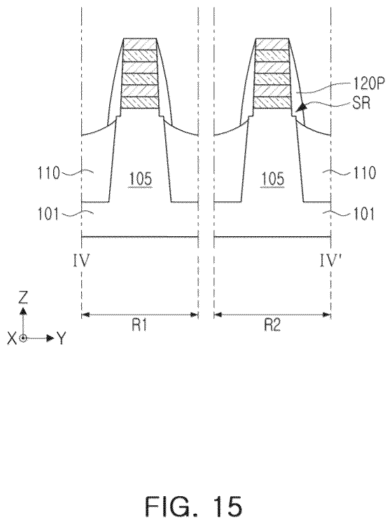

Referring to FIG. 15, a device isolation layer 110 and preliminary sidewall spacer layers 120P may be formed.

The device isolation layer 110 may be formed by depositing an insulating material to fill a space between the active structures, and then partially removing the deposited insulating material from the upper portion to expose at least a portion of the active regions 105. In the present operation, the level and shape of the upper surface of the device isolation layer 110 may be variously changed. The first mask layer ML1 may be removed during the formation process of the device isolation layer 110, or may be removed thereafter.

Preliminary sidewall spacer layers 120P may be formed on side surfaces of the patterned structures of the sacrificial layers 119 and the first to third channel layers 141, 142, and 143, and lower ends thereof may be disposed on the device isolation layer 110. The preliminary sidewall spacer layers 120P may further at least partially cover the side surfaces of the active regions 105 exposed from the device isolation layer 110, and at least partially cover the step regions SR.

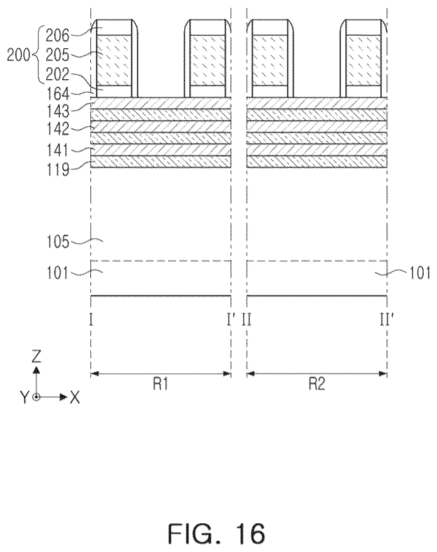

Referring to FIG. 16, sacrificial gate structures 200 and gate spacer layers 164 may be formed on the active structures.

The sacrificial gate structures 200 may be sacrificial structures formed in regions in which gate dielectric layers 162 and gate electrodes 165 are disposed on the channel structures 140 through subsequent processes, as shown in FIGS. 2A and 2B. The sacrificial gate structures 200 may have a line shape extending in one direction while intersecting the active structures. The sacrificial gate structures 200 may extend, for example, in a Y-direction.

Each of the sacrificial gate structures 200 may include first and second sacrificial layers 202 and 205 and a mask pattern layer 206 sequentially stacked. The first and second sacrificial gate layers 202 and 205 may be patterned using a mask pattern layer 206. The first and second sacrificial gate layers 202 and 205 may be an insulating layer and a conductive layer, respectively, but the present disclosure is not limited thereto, and the first and second sacrificial gate layers 202 and 205 may be formed as a single layer. For example, the first sacrificial gate layer 202 may include silicon oxide, and the second sacrificial gate layer 205 may include polysilicon. The mask pattern layer 206 may include a silicon oxide and/or silicon nitride.

Gate spacer layers 164 may be formed on both sidewalls of the sacrificial gate structures 200. The gate spacer layers 164 may be formed of a low-K material, and may include, for example, at least one of SiO, SiN, SiCN, SiOC, SiON, or SiOCN.

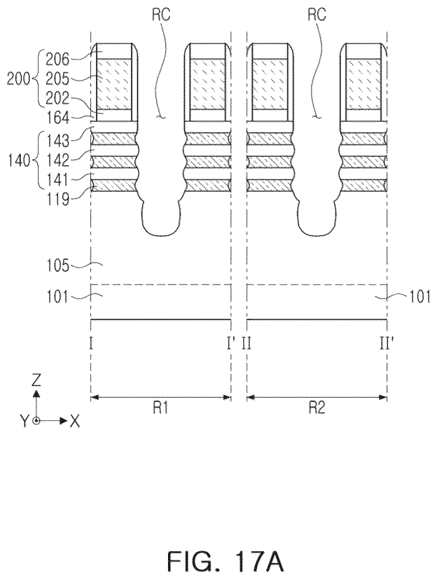

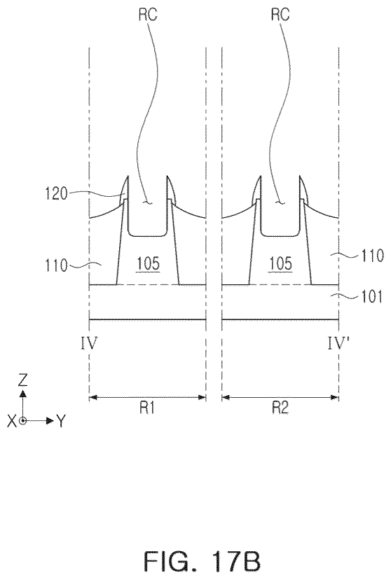

Referring to FIGS. 17A and 17B, the sacrificial layers 119 and the first to third channel layers 141, 142, and 143 exposed by the sacrificial gate structures 200 may be partially removed to form recess regions RC.

By using the sacrificial gate structures 200 and the gate spacer layers 164 as a mask, a portion of the exposed sacrificial layers 119 and a portion of the first to third channel layers 141, 142, and 143 may be removed, and a portion of the active regions 105 may be removed to form recess regions RC. Thereby, the first to third channel layers 141, 142, and 143 can form channel structures 140 having a limited length in an X-direction.

The present operation may include, for example, a first recess process for forming preliminary recess regions below the first channel layer 141, and a second recess process for forming sacrificial spacer layers on sidewalls of the preliminary recess regions and additionally removing the active region 105 to form recess regions RC. However, the formation process of the recess regions RC may be variously changed in the one or more embodiments.

In the present operation, on the outside of the sacrificial gate structures 200, the active regions 105 may be removed from the upper portions of the step regions SR when forming the recess regions RC. As illustrated in FIG. 17B, the active regions 105 may have a shape in which both ends thereof in the Y-direction protrude upwardly, while surrounding the recess regions RC below the step regions SR. Since the active regions 105 have step regions SR, the active regions 105 may remain stably on the side walls of the recess regions RC at a predetermined thickness in the present operation. On the outside of the sacrificial gate structures 200, a portion of the preliminary sidewall spacer layers 120P may be removed when forming the recess regions RC, so that sidewall spacer layers 120 may be formed.

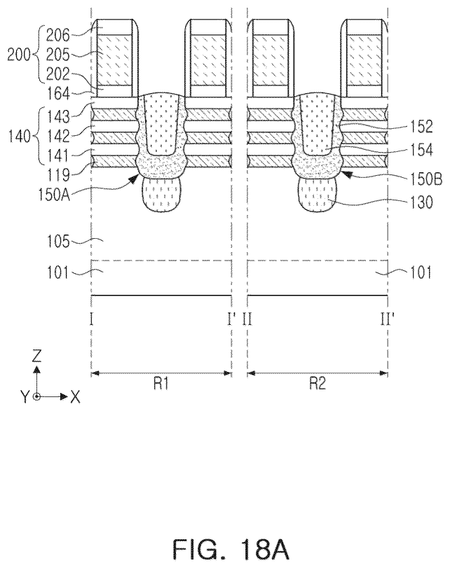

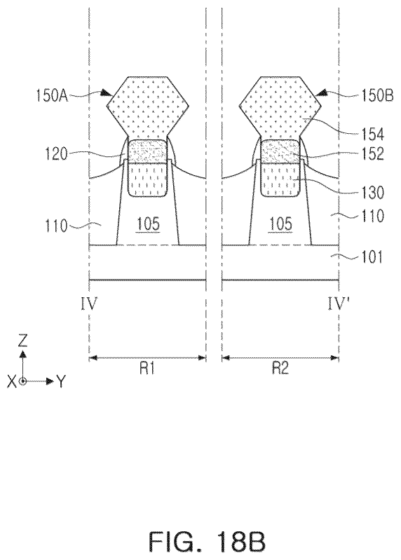

Referring to FIGS. 18A and 18B, place holder layers 130 and first and second source/drain regions 150A and 150B may be formed in the recess regions RC.

The place holder layers 130 may be formed by being grown from the active regions 105, for example, by a selective epitaxial process. As illustrated in FIG. 18B, since the place holder layers 130 are formed by being grown from upper surfaces of the active regions 105 and side surfaces of the protruding regions on both sides in the Y-direction, the place holder layers 130 may have substantially flat upper surfaces, as compared to a case in which the place holder layers 130 are grown only from the upper surfaces of the active regions 105, and dispersion of the shape between the place holder layers 130 may be minimized. The place holder layers 130 may include a semiconductor material having a different composition from the first and second source/drain regions 150A and 150B. After the place holder layers 130 are formed, the sacrificial spacer layers may be removed.

The first and second source/drain regions 150A and 150B may be formed by being grown from side surfaces of the channel structures 140, the active regions 105, and the place holder layers 130, for example, by a selective epitaxial process. In one or more embodiments, the first and second source/drain regions 150A and 150B may be formed by different processes, and may have different compositions. The first and second source/drain regions 150A and 150B may include impurities by in-situ doping. Each of the first and second source/drain regions 150A and 150B may include first and second epitaxial layers 152 and 154. The first and second epitaxial layers 152 and 154 may have different concentrations of non-silicon elements. Since the place holder layers 130 are formed in a stable shape as described above, the dispersion of the shape of the first and second epitaxial layers 152 and 154 may also be minimized.

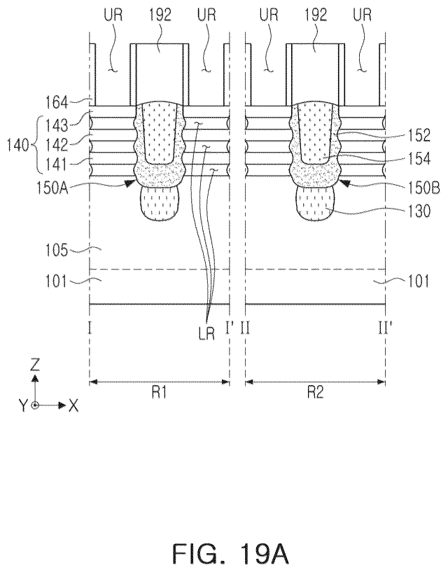

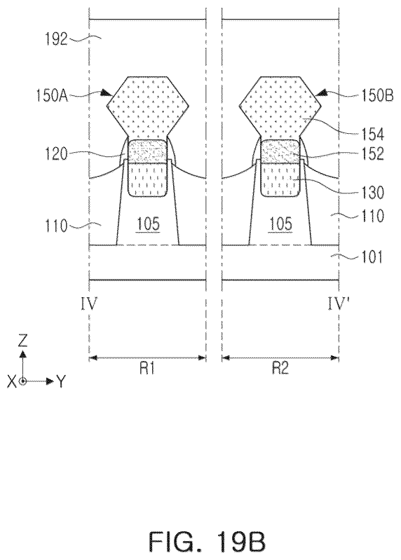

Referring to FIGS. 19A and 19B, a first interlayer insulating layer 192 may be formed, and sacrificial layers 119 and a sacrificial gate structure 200 may be removed.

The first interlayer insulating layer 192 may be formed by forming an insulating film at least partially covering the sacrificial gate structure 200 and the first and second source/drain regions 150A and 150B and performing a planarization process.

The sacrificial layers 119 and the sacrificial gate structure 200 may be selectively removed with respect to the gate spacer layers 164, the first interlayer insulating layer 192, the first and second source/drain regions 150A and 150B, and the channel structures 140. First, the sacrificial gate structure 200 may be removed to form an upper gap region UR, and then the sacrificial layers 119 exposed through the upper gap region UR may be removed to form lower gap regions LR. For example, when the sacrificial layers 119 include silicon germanium (SiGe) and the channel structures 140 include silicon (Si), the sacrificial layers 119 may be selectively removed by performing a wet etching process.

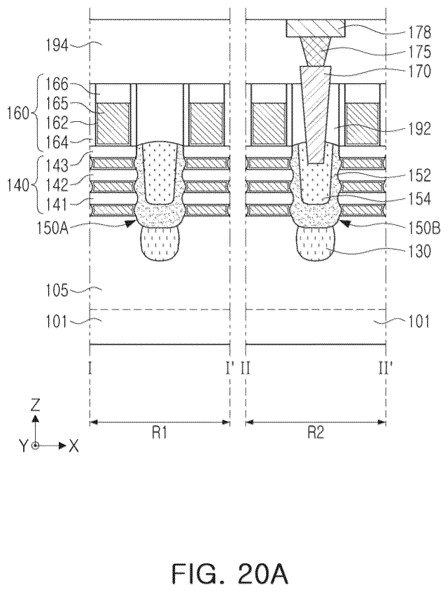

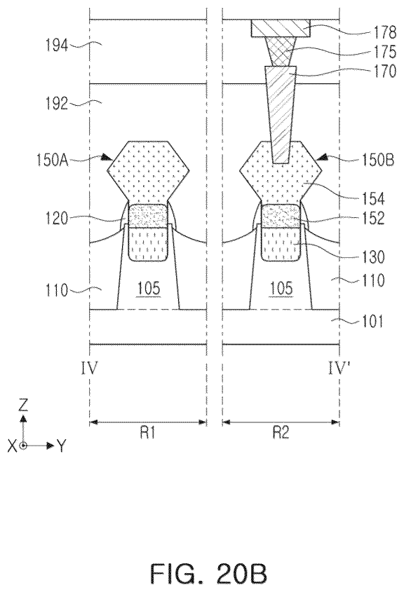

Referring to FIGS. 20A and 20B, gate structures 160 may be formed, and a second interlayer insulating layer 194, a front contact plug 170, an upper contact 175, and an upper interconnection line 178 may be formed.

Gate dielectric layers 162 and gate electrodes 165 may be formed to fill the upper gap regions UR and the lower gap regions LR. The gate dielectric layers 162 may be formed to conformally cover at least a portion of inner surfaces of the upper gap regions UR and the lower gap regions LR. After the gate electrodes 165 are formed to completely fill the upper gap regions UR and the lower gap regions LR, the gate electrodes 165 may be removed from the upper gap regions UR to a predetermined depth together with the gate dielectric layers 162 and the gate spacer layers 164, and gate capping layers 166 may be formed in the removed regions.

A second interlayer insulating layer 194 may be formed on the gate structures 160. After forming a portion of the second interlayer insulating layer 194, a front contact plug 170 penetrating a portion of the second interlayer insulating layer 194 and the first interlayer insulating layer 192 may be formed. An upper contact 175 and an upper interconnection line 178 may be sequentially formed on the front contact plug 170. If there is an additional interconnection structure disposed on the upper interconnection line 178, the interconnection structure may be further formed in the present operation.

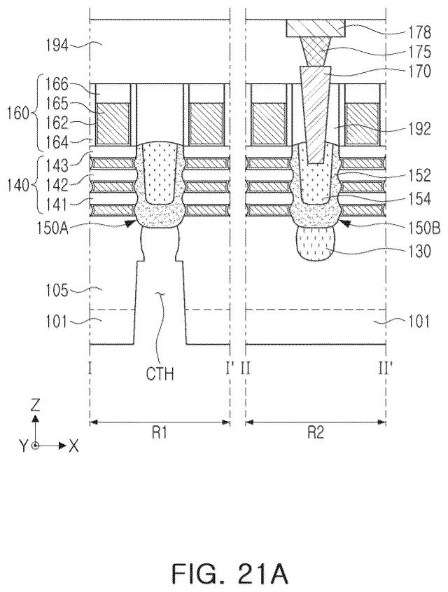

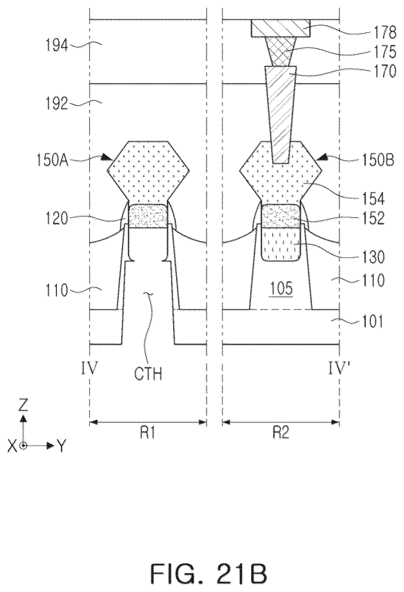

Referring to FIGS. 21A and 21B, after forming a contact hole CTH exposing a place holder layer 130 below the first source/drain region 150A, the place holder layer 130 may be removed.

Although not specifically shown, in order to perform the process from a lower surface of the substrate 101, a separate carrier substrate may be formed on the second interlayer insulating layer 194 and the entire structure may be turned over to perform the following processes.

A separate mask layer is formed on the lower surface of the substrate 101, a contact hole CTH penetrating the substrate 101 and the active region 105 to expose the place holder layer 130 below the first source/drain region 150A, and then the exposed place holder layer 130 may be selectively removed. Since the place holder layer 130 is formed to be stably spaced apart from a second epitaxial layer 154, when the place holder layer 130 is removed, the place holder layer 130 may be removed without damaging the second epitaxial layer 154.

In the case of the example embodiment of FIGS. 8 to 9C, it may be manufactured by removing the substrate 101 and active regions 105 and forming a substrate insulating layer 190, before forming the contact hole CTH. The substrate 101 and the active regions 105 may be thinned by removing a portion thereof, for example, by a lapping, grinding, and/or polishing process, and the remaining region may also be removed by an etching and/or oxidation process. In one or more embodiments, only a portion of the substrate 101 or active regions 105 may be removed.

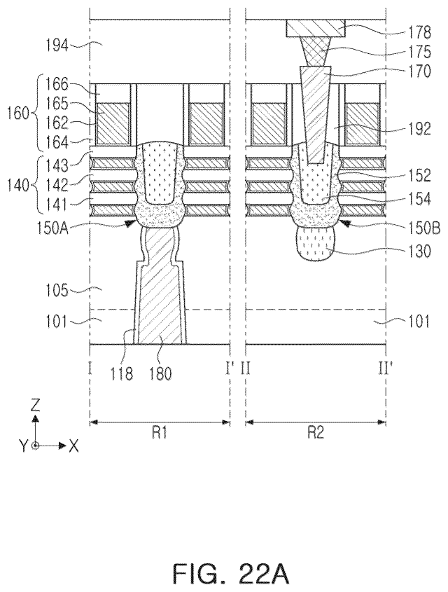

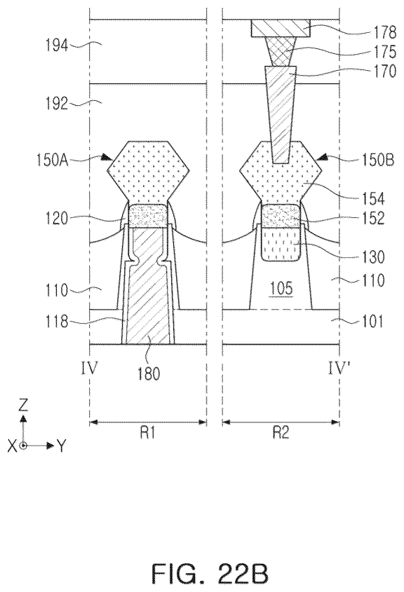

Referring to FIGS. 22A and 22B, a contact insulating layer 118 and a backside contact plug 180 may be formed.

The contact insulating layer 118 may be formed on a substrate 101 and an active region 105 exposed through a contact hole CTH. The contact insulating layer 118 may be formed, for example, by nitriding or oxidizing the substrate 101 and the active region 105. In this case, a nitride or oxide may also be formed on a lower surface of the first source/drain region 150A, which may be removed by an additional process. Alternatively, the contact insulating layer 118 may be formed by depositing an insulating material on an inner surface of the contact hole CTH.

The backside contact plug 180 may be formed by filling a conductive material into the contact hole CTH. When the backside contact plug 180 includes a metal-semiconductor compound layer, the metal-semiconductor compound layer may be first formed along the surface of the first source/drain region 150A exposed through the contact hole CTH, and then a conductive layer filling the contact hole CTH may be formed.

Next, referring to FIGS. 2A to 2C, a third interlayer insulating layer 196 may be formed on a lower surface of the substrate 101, a portion of the third interlayer insulating layer 196 may be removed to form a backside power structure 185 connected to the backside contact plug 180. Thereby, the semiconductor device 100 of FIGS. 1 to 2C may be manufactured.

As set forth above, by optimizing a shape of an active region and uniformly forming a place holder layer, a semiconductor device having improved reliability may be provided.

Although the above-described semiconductor devices take a form of the nanosheet transistor or MBCFET structure, the disclosure is not limited thereto. Thus, the disclosure may apply to different types of field-effect transistor such as FinFET, vertical FET, forksheet transistor, etc.

The various advantages and effects of the present disclosure are not limited to the above-described content, and can be more easily understood through description of specific embodiments of the present disclosure.

While one or more embodiments have been illustrated and described above, it will be apparent to those skilled in the art that modifications and variations could be made without departing from the scope of the present disclosure as defined by the appended claims.

What is claimed is:

1. A semiconductor device comprising:
active regions extending in a first direction on a substrate;
a device isolation layer defining the active regions on the substrate;
gate structures intersecting the active regions on the substrate and extending in a second direction;
a plurality of channel layers on the active regions, wherein the plurality of channel layers are spaced apart from each other in a third direction perpendicular to an upper surface of the substrate, and are surrounded by the gate structures;
source/drain regions comprising a first source/drain region and a second source/drain region spaced apart from each other, wherein the source/drain regions are in recess regions in which the active regions are recessed on both sides of the gate structures, and wherein the source/drain regions are connected to the plurality of channel layers;
sidewall spacer layers on a portion of each side surface of each of the source/drain regions in the second direction; and
a backside contact plug penetrating a first active region among the active regions, and contacting a lower surface of the first source/drain region,
wherein each of the active regions comprises a step region in which a width of each of the active regions in the second direction increases below the plurality of channel layers, and
wherein the first active region extends onto side surfaces of at least an upper region of the backside contact plug in the second direction.

2. The semiconductor device of claim 1, wherein each of the active regions comprises a first width in the second direction on the step region, a second width greater than the first width below the step region, and a surface extending horizontally in the step region.

3. The semiconductor device of claim 2, wherein a difference between the second width and the first width is within a range of about 2 nm to about 5 nm.

4. The semiconductor device of claim 1, wherein, on an outside of the gate structures, an upper end of the first active region is located on a level higher than an upper end of the backside contact plug.

5. The semiconductor device of claim 1, wherein the first active region comprises a point at which a thickness of the first active region is changed on side surfaces of the backside contact plug in the second direction.

6. The semiconductor device of claim 1, wherein the sidewall spacer layers are on upper ends of the active regions and extend onto the device isolation layer.

7. The semiconductor device of claim 6, wherein the upper ends of the active regions, and upper ends of the device isolation layer adjacent thereto, are in contact with the sidewall spacer layers and are located on different levels.

8. The semiconductor device of claim 1, further comprising:
a place holder layer within the recess region below the second source/drain region,
wherein side surfaces of the place holder layer in the second direction are at least partially covered with a second active region among the active regions.

9. The semiconductor device of claim 8,
wherein the second source/drain region comprises a first epitaxial layer on an inner surface of the recess region and a second epitaxial layer on the first epitaxial layer, and
wherein the second epitaxial layer is spaced apart from the place holder layer by the first epitaxial layer.

10. The semiconductor device of claim 1, wherein the backside contact plug is in a recess of the lower surface of the first source/drain region.

11. The semiconductor device of claim 1, further comprising:
a contact insulating layer between the backside contact plug and the first active region.

12. The semiconductor device of claim 1, further comprising:
a front contact plug in a recess of an upper surface of the second source/drain region.

13. A semiconductor device comprising:
an active region extending in a first direction on a substrate;
a gate structure intersecting the active region on the substrate and extending in a second direction;
a plurality of channel layers on the active region, wherein the plurality of channel layers are spaced apart from each other in a third direction perpendicular to an upper surface of the substrate and are surrounded by the gate structure;
a first source/drain region and a second source/drain region, wherein the first and the second source/drain regions are in recess regions in which the active region is recessed on both sides of the gate structure, and wherein the first and the second source/drain regions are connected to the plurality of channel layers; and
a backside contact plug contacting a lower surface of the first source/drain region,
wherein the active region extends onto a side surface of the backside contact plug in the second direction.

14. The semiconductor device of claim 13, wherein an upper end of the active region is located on an outside of the gate structure and is on a level higher relative to the substrate than an upper end of the backside contact plug.

15. The semiconductor device of claim 13, wherein the active region is on a portion of a side surface of the first source/drain region in the second direction.

16. The semiconductor device of claim 13, wherein the active region comprises a step region in which a width of the active region in the second direction is changed below the gate structure and the plurality of channel layers.

17. The semiconductor device of claim 13, further comprising:
an isolation structure penetrating the active region and connected to a lowermost surface of the gate structure, wherein the isolation structure comprises an insulating material.

18. The semiconductor device of claim 13, further comprising:
a sidewall spacer layer on an upper end of the active region on an outside of the gate structure.

19. A semiconductor device comprising:
a substrate structure;
source/drain regions comprising a first source/drain region and a second source/drain region spaced apart from each other;
gate structures extending in one direction on the substrate structure, wherein the source/drain regions are arranged on either side of the gate structures;
sidewall spacer layers on a portion of each of side surface of the source/drain regions on an outside of the gate structures;
a backside contact plug connected to the first source/drain region through a lower surface of the first source/drain region; and
a place holder layer below the second source/drain region,
wherein an upper end of the substrate structure protrudes into the sidewall spacer layers on the outside of the gate structures.

20. The semiconductor device of claim 19, wherein the substrate structure comprises a semiconductor material or an insulating material.
